(19) United States
(12) Patent Application Publication
(10) Pub. No.: US 2023/0033348 A1
(43) Pub. Date: Feb. 2, 2023

(54) NON-VOLATILE MEMORY DEVICES WITH A CHARGE-DETRAP MECHANISM

(71) Applicant: GLOBALFOUNDRIES Singapore Pte. Ltd., Singapore (SG)

(72) Inventors: SHYUE SENG TAN, Singapore (SG); XINSHU CAI, Singapore (SG); ENG HUAT TOH, Singapore (SG); MYO AUNG MAUNG, Singapore (SG)

(21) Appl. No.: 17/391,052

(22) Filed: Aug. 2, 2021

(51) Int. Cl. H01L 29/423; H01L 29/788; H01L 21/28; H01L 29/66

(52) U.S. Cl. CPC H01L 29/42328; H01L 29/7883; H01L 29/40114; H01L 29/66825

(57) ABSTRACT

A semiconductor device is provided. The semiconductor device includes a memory cell and a charge-detrap electrode. The memory cell includes a substrate, a floating gate having a first side and a second side laterally opposite the first side, and a gate electrode. The substrate further includes a source region and a drain region, and a channel region arranged between the source region and the drain region. The floating gate is arranged over the channel region and the gate electrode is arranged adjacent to the first side of the floating gate. The charge-detrap electrode is arranged adjacent to the second side of the floating gate.

### TECHNICAL FIELD

The present disclosure relates generally to semiconductor devices, and more particularly to non-volatile memory devices having a charge-detrap mechanism and methods of forming the same.

### BACKGROUND

Semiconductor devices, such as logic and memory devices, may provide a wide range of applications. In particular, memory devices are widely used in semiconductor chips and can be generally divided into volatile memory devices and non-volatile memory (NVM) devices. Volatile memory devices, such as a static random access memory (SRAM) device, require a supply of electric power to retain stored data but lose the data when the supply of electric power is interrupted. On the other hand, NVM devices, such as flash memory devices, retain the stored data even without a supply of electric power.

The NVM devices may utilize a charge retention mechanism to store data. For example, charges may be stored in a floating gate of an NVM device during a program operation and the stored charges may be expelled from the floating gate during an erase operation.

However, the data retention ability of the NVM devices may degrade over time. For example, the stored charges may not get expelled from an NVM device effectively during an erase operation and accumulate in the NVM device over time. This may result in a limited number of program cycles and erase cycles and/or high latency in program speed and erase speed of the NVM device.

Therefore, in order to provide NVM devices with an improved product lifecycle and device performance, NVM devices with a charge-detrap mechanism and methods of forming the same are provided to overcome, or at least ameliorate, the disadvantages described above.

### SUMMARY

To achieve the foregoing and other aspects of the present disclosure, non-volatile memory (NVM) devices with a charge-detrap mechanism and methods of forming the same are presented.

According to an aspect of the present disclosure, a semiconductor device is provided. The semiconductor device includes a memory cell and a charge-detrap electrode. The memory cell includes a substrate, a floating gate having a first side and a second side laterally opposite the first side, and a gate electrode. The substrate further includes a source region and a drain region, and a channel region arranged between the source region and the drain region. The floating gate is arranged over the channel region and the gate electrode is arranged adjacent to the first side of the floating gate. The charge-detrap electrode is arranged adjacent to the second side of the floating gate.

According to another aspect of the present disclosure, a semiconductor device is provided. The semiconductor device includes a plurality of memory cells and a charge-detrap electrode. Each memory cell includes a substrate, a floating gate having a first side and a second side laterally opposite the first side, and a gate electrode. The substrate further includes a source region and a drain region, and a channel region arranged between the source region and the drain region. The floating gate is arranged over the channel region and the gate electrode is arranged adjacent to the first side of the floating gate. The charge-detrap electrode is arranged parallel to the plurality of memory cells and adjacent to the second side of the floating gate laterally opposite the first side of each memory cell.

According to yet another aspect of the present disclosure, a method of forming a semiconductor device is provided. The method includes forming a source region in a substrate and forming a drain region in the substrate spaced apart from the source region. A floating gate is formed over the substrate, and between the source region and the drain region. A gate electrode and a charge-detrap electrode are formed at laterally opposite sides of the floating gate, such that the gate electrode is at least partially arranged over the drain region and the charge-detrap electrode is at least partially arranged over the source region.

### BRIEF DESCRIPTION OF THE DRAWINGS

The embodiments of the present disclosure will be better understood from a reading of the following detailed description, taken in conjunction with the accompanying drawings.

FIG. 1A is a plan view of a non-volatile memory device, according to an embodiment of the disclosure.

FIG. 1B is a cross-sectional view of the non-volatile memory device in FIG. 1A, taken along a line A-A', according to an embodiment of the disclosure.

FIGS. 2A to 2E are cross-sectional views that illustrate a method of forming the non-volatile memory in FIG. 1B, according to an embodiment of the disclosure.

FIG. 3 is a cross-sectional view of a non-volatile memory device, according to an alternative embodiment of the disclosure.

For simplicity and clarity of illustration, the drawings illustrate the general manner of construction, and certain descriptions and details of features and techniques may be omitted to avoid unnecessarily obscuring the discussion of the described embodiments of the device.

Additionally, elements in the drawings are not necessarily drawn to scale. For example, the dimensions of some of the elements in the drawings may be exaggerated relative to other elements to help improve understanding of embodiments of the device. The same reference numerals in different drawings denote the same elements, while similar reference numerals may, but do not necessarily, denote similar elements.

### DETAILED DESCRIPTION

The present disclosure relates to non-volatile memory (NVM) devices with a charge-detrap mechanism and methods of forming the same. The NVM device may include a memory cell that utilizes a charge retention mechanism, for example, a flash memory cell, an erasable programmable read-only memory (EPROM) cell, or an electrically erasable and programmable read-only memory (EEPROM) cell.

The charge retention mechanism may include utilizing a floating gate to store charges. The floating gate may be arranged over a channel region that is formed between a source region and a drain region of the memory cell. The memory cell may further include a gate dielectric layer separating the floating gate from the channel region, a gate electrode, and a tunnel barrier layer.

To program a memory cell, a hot carrier injection (HCI) mechanism may be utilized. A sufficiently large potential difference may be applied between the source region and a gate electrode such that charges from the source region may accelerate towards the drain region through the channel region. The charges may become heated and may get injected into the floating gate through the gate dielectric layer. The floating gate may become sufficiently negatively charged and the memory cell may be considered to be in state “0”.

To erase a programmed memory cell, a Fowler-Nordheim (FN) tunneling mechanism may be utilized. A sufficiently high voltage may be applied to the gate electrode such that the gate electrode is at a higher potential than the source region and the drain region to generate an electric field such that charges in the floating gate may tunnel to the gate electrode through the tunnel barrier layer. The floating gate may be sufficiently discharged of charges and may be considered to be in state “1”.

As the memory cell undergoes iterative cycling of a program operation and an erase operation, the gate dielectric layer and/or the tunnel barrier layer may be damaged by electrical effects, such as HCI and FN tunneling, and undesirable electron traps may be formed therewithin, trapping charges. The trapped charges undesirably affect the device performance and minimizing the product lifecycle of the memory cell with a reduced number of program and erase cycles.

Various embodiments of the present disclosure are now described in detail with accompanying drawings. It is noted that like and corresponding elements are referred to by the use of the same reference numerals. The embodiments disclosed herein are exemplary, and not intended to be exhaustive or limiting to the disclosure.

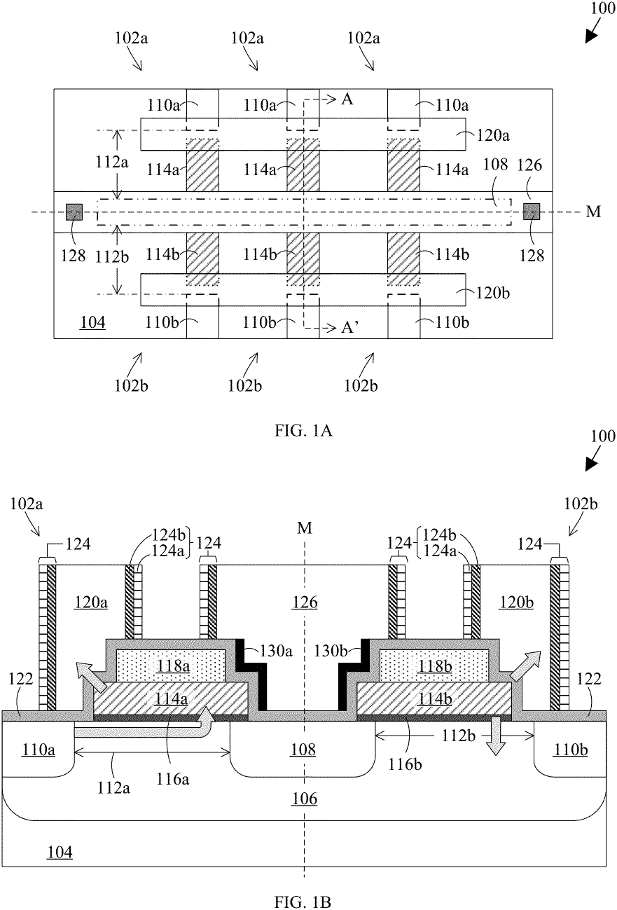

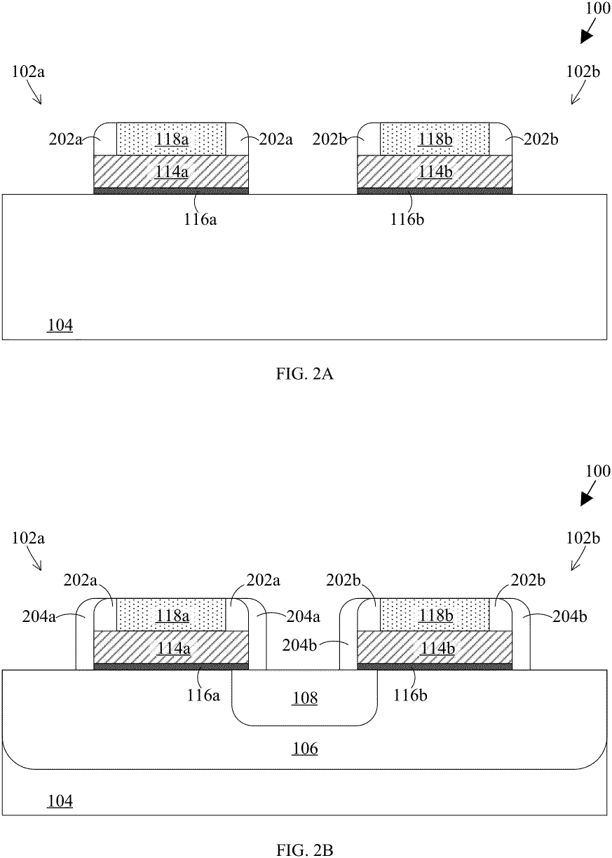

FIG. 1A is a plan view of an NVM device 100 and FIG. 1B is a cross-sectional view of the NVM device 100 of FIG. 1A, taken along a line A-A’, according to an embodiment of the disclosure. The NVM device 100 may be arranged in a memory cell region of a semiconductor device and the NVM device 100 may be part of a plurality of NVM devices arranged in an array configuration of rows and columns in the memory cell region. Only one NVM device is illustrated for clarity purposes.

The NVM device 100 may include a plurality of memory cells, for example, a plurality of memory cells 102a arranged in a row configuration and a plurality of memory cells 102b also arranged in a row configuration; the row of memory cells 102b may be arranged adjacent to and parallel to the row of memory cells 102a. In an embodiment of the disclosure, each memory cell 102a may be further aligned with a memory cell 102b in a column configuration to form an array configuration of memory cells in the memory cell region.

The NVM device 100 may be fabricated over a substrate 104. The substrate 104 may include a semiconductor material, such as silicon, silicon germanium, silicon carbide, other II-VI or III-V semiconductor compounds, and the like. Furthermore, the substrate 104 may be in a form of a bulk semiconductor substrate or a layered semiconductor substrate, such as a semiconductor-on-insulator (SOI) substrate.

The substrate 104 may include a plurality of doped regions, for example, a memory well region 106, a source region 108, a plurality of drain regions 110a, and a plurality of drain regions 110b. The source region 108, the plurality of drain regions 110a, and the plurality of drain regions 110b may be arranged at least partially within the substrate 104 in the memory well region 106.

The source region 108 may include a terminal (not shown) to provide program functionality to the NVM device 100 and may be arranged parallel to and extend in the same direction as the row of memory cells 102a and the row of memory cells 102b. In an embodiment of the disclosure, the source region 108 may be a shared source region for each memory cell 102a in the row and may form a source line. In another embodiment of the disclosure, the source region 108 may be arranged between and function as a shared source region for each memory cell 102a in the row and each memory cell 102b in the row.

The plurality of drain regions 110a may include a discrete drain region 110a for each memory cell 102a and the plurality of drain regions 110b may include a discrete drain region 110b for each memory cell 102b. Each drain region 110a of the memory cell 102a may be electrically coupled with the drain region 110b of the adjacent memory cell 102b that is arranged in the same column to form a bit line. The bit line may be perpendicular to the source line of the NVM device 100. As illustrated in FIG. 1B, a channel region 112a may be formed between the source region 108 and the drain region 110a of the memory cell 102a, and a channel region 112b may be formed between the source region 108 and the drain region 110b of the memory cell 102b.

Referring to the row of memory cells 102a in FIG. 1A and FIG. 1B, each memory cell 102a may include a floating gate 114a and a gate dielectric layer 116a. The gate dielectric layer 116a may be arranged between the floating gate 114a and the substrate 104. The floating gate 114a may be arranged at least partially over the channel region 112a. For example, a portion of the floating gate 114a may be arranged over the channel region 112a and another portion of the floating gate 114a may be arranged over the source region 108, as illustrated in FIG. 1B. In another example, the floating gate 114a may be arranged over the entire channel region 112a, even though this embodiment is not illustrated in the accompanying drawings.

The row of memory cells 102a may further include a mask layer 118a and a gate electrode 120a. The mask layer 118a may be over the floating gate 114a of each memory cell 102a. The mask layer 118a may at least protect the floating gate 114a during subsequent fabrication processes by minimizing any potential damage that may be caused to the floating gate 114a.

The gate electrode 120a may be arranged parallel to and extend in the same direction as the row of memory cells 102a. The gate electrode 120a may be a shared gate electrode for the row of memory cells 102a to form a word line. The gate electrode 120a may be a dual-function gate electrode, for example, the gate electrode 120a may function as both a select gate and an erase gate of the row of memory cells 102a. The gate electrode 120a may include a portion arranged adjacent to and over the mask layer 118a and may further include another portion arranged adjacent to and over the floating gate 114a of each memory cell 102a; the portion of the floating gate 114a underlying the gate electrode 120a is illustrated with a dotted outline in FIG. 1A.

The gate electrode 120a may be arranged at least partially over the channel region 112a and the drain region 110a of each memory cell 102a and may be arranged closer to the drain region 110a than the source region 108. The gate electrode 120a may be further arranged at least partially over the drain region 110a of each memory cell 102a; the portion of the drain region 110a underlying the gate electrode 120a is illustrated with a dashed outline in FIG. 1A.

The row of memory cells 102a may further include a charge-detrap electrode 126. The charge-detrap electrode 126 may be arranged parallel to and extend in the same direction as the row of memory cells 102a. The charge-detrap electrode 126 may traverse across the row of memory cells 102a. For example, the charge-detrap electrode 126 may be arranged over the source region 108; the source region 108 underlying the charge-detrap electrode 126 is illustrated with a dash-dot-dot outline in FIG. 1A. The charge-detrap electrode 126 may include a portion arranged adjacent to and over the mask layer 118a and may further include another portion arranged adjacent to and over the floating gate 114a of each memory cell 102a; the portion of the floating gate 114a underlying the charge-detrap electrode 126 is illustrated with a dotted outline in FIG. 1A.

A tunnel barrier layer 122 may be at least partially arranged between the charge-detrap electrode 126 and the memory cell 102a to electrically isolate the charge-detrap electrode 126 therefrom. For example, the tunnel barrier layer 122 may be arranged between the charge-detrap electrode 126 and the mask layer 118a, the floating gate 114a, and the source region 108. The tunnel barrier layer 122 may electrically isolate the charge-detrap electrode 126 from adjacent conductive features, such as the floating gate 114a and the source region 108. The tunnel barrier layer 122 may further separate and electrically isolate the gate electrode 120a from the mask layer 118a, the floating gate 114a, and the drain region 110a.

The charge-detrap electrode 126 may be suitable to initiate a charge-detrap operation. The charge-detrap operation may include using the charge-detrap electrode 126 to generate sufficient thermal energy to perform an electro-thermal annealing process; for example, the charge-detrap electrode 126 may function as a heating element. Contacts 128 may be provided at the end portions of the charge-detrap electrode 126 to enable electrical connectivity to the charge-detrap electrode 126.

Each memory cell 102a may further include spacers 124. The spacers 124 may be arranged over sidewalls of the gate electrode 120a and the charge-detrap electrode 126. The spacers 124 may serve to electrically isolate the gate electrode 120a and the charge-detrap electrode 126 from adjacent conductive features. The spacers 124 may include a single-layered dielectric material or a multi-layered dielectric material. In this embodiment of the disclosure, the spacers 124 may be a multi-layered dielectric material, including a dielectric material 124a and a dielectric material 124b.

Each memory cell 102a may yet further include a dielectric liner 130a. The dielectric liner 130a may be arranged over a portion of the tunnel barrier layer 122 such that the dielectric liner 130a may be adjacent to at least a portion of the mask layer 118a and the floating gate 114a.

Referring to the row of memory cells 102b in FIG. 1A and FIG. 1B, the row of memory cells 102b may be a mirror image of the row of memory cells 102a, i.e., the row of memory cells 102b having mirror symmetry about an axis M through the center of the source region 108. However, the NVM device 100 may not include the row of memory cells 102a and the memory cells 102b. For example, the NVM device 100 may include only the row of memory cells 102a or the row of memory cells 102b.

Similar to the row of memory cells 102a, the row of memory cells 102b may include a floating gate 114b, a gate dielectric layer 116b arranged between the floating gate 114b and the substrate 104, a mask layer 118b, and a gate electrode 120b. The floating gate 114b may be arranged over the channel region 112b. The mask layer 118b may be arranged over the floating gate 114b. The gate electrode 120b may include a portion arranged adjacent to and over the mask layer 118b and may further include another portion arranged adjacent to and over the floating gate 114b of each memory cell 102b; the portion of the floating gate 114b underlying the gate electrode 120b is illustrated with a dotted outline in FIG. 1A. The gate electrode 120b may be further arranged over the channel region 112b and the drain region 110b of each memory cell 102b; the portion of the drain region 110b underlying the gate electrode 120b is illustrated with a dashed outline in FIG. 1A.

The charge-detrap electrode 126 may be shared between the row of memory cells 102a and the row of memory cells 102b by positioning the charge-detrap electrode 126 therebetween. The charge-detrap electrode 126 may include a portion arranged adjacent to and over the mask layer 118b and may further include another portion arranged adjacent to and over the floating gate 114b of each memory cell 102b; the portion of the floating gate 114b underlying the charge-detrap electrode 126 is illustrated with a dotted outline in FIG. 1A.

The tunnel barrier layer 122 of each memory cell 102a may extend over to the adjacent memory cell 102b that is arranged in the same column, as illustrated in FIG. 1B. Similar to the memory cell 102a, the tunnel barrier layer 122 may separate and electrically isolate the charge-detrap electrode 126 from the mask layer 118b, the floating gate 114b, and the source region 108. The tunnel barrier layer 122 may further separate and electrically isolate the gate electrode 120b from the mask layer 118b, the floating gate 114b, and the drain region 110b.

Similar to the memory cell 102a, the spacers 124 may be arranged over sidewalls of the gate electrode 120b. The spacers 124 may serve to electrically isolate the gate electrode 120b from adjacent conductive features. In an embodiment of the disclosure, each memory cell 102b may additionally include a dielectric liner 130b. The dielectric liner 130a may be arranged over a portion of the tunnel barrier layer 122 such that the dielectric liner 130b may be adjacent to at least a portion of the mask layer 118b and the floating gate 114b.

The NVM device 100 may be operated by applying appropriate electrical signals thereto. Table 1 below shows a set of exemplary electrical signals that may be applied to a memory cell, for example, the memory cell 102a, for a program operation, an erase operation, and a read operation. Varying levels of electrical signals may be utilized, depending on the design and technology node of the memory cell, without departing from the spirit and scope of the present disclosure.

Table 1

| Operation | Source Region | | Gate Electrode | | Drain Region | | Charge-Detrap Electrode | Duration |
|---|---|---|---|---|---|---|---|---|
| | Select | UnSelect | Select | UnSelect | Select | UnSelect | | |
| Program | 8 V | 0 V | 1.5 V | 0 V | 1 uA | 2.5 V | Float | 10 µs |
| Erase | 0 V | 0 V | 12 V | 0 V | 0 V | 0 V | Float | 10 ms |
| Read | 0 V | 0 V | 2.5 V | 0 V | 0.9 V | 0 V | Float | |
| Charge-Detrap | 0 V | 0 V | 0 V | 0 V | 0 V | 0 V | 2.5 V | 1 ms ~ 1 s |

To program a selected memory cell 102a, a voltage of 8 V may be applied to the source region 108, a voltage of 1.5 V may be provided to the gate electrode 120a, and a constant current of 1 uA may be applied to the corresponding drain region 110a for a duration of approximately 10 µs. To erase the selected memory cell 102a, voltages of 0 V, 12 V, and 0 V may be applied to the source region 108, the gate electrode 120a, and the corresponding drain region 110a, respectively, for a duration of approximately 10 ms. To read the selected memory cell 102a, voltages of 0 V, 2.5 V, and 0.9 V may be provided to the source region 108, the gate electrode 120a, and the corresponding drain region 110a, respectively. The flow of charges for the program operation and the erase operation of the memory cell 102a are indicated by arrows in FIG. 1B. Similar electrical signals may be applied to the memory cell 102b for a program operation, an erase operation, or a read operation.

During the operation of the selected memory cell 102a, i.e., for a program operation, an erase operation, or a read operation, the charge-detrap electrode 126 may be floating, i.e., no electrical signals are being applied thereto and no current flows through the charge-detrap electrode 126. To initiate a charge-detrap operation for a memory cell, for example, the memory cell 102a, a single pulse or multiple pulses of voltages may be applied to the charge-detrap electrode 126 by applying a potential difference between the end portions of the charge-detrap electrode 126 through the contacts 128. An exemplary set of voltages is provided in Table 1 above. For example, voltages of 0 V may be applied to the source region 108, the gate electrode 120a, and the corresponding drain region 110a, and 2.5 V may be applied to the charge-detrap electrode 126. Similar electrical signals may be applied to the memory cell 102b for a charge-detrap operation; the flow of charges for the charge-detrap operation of the memory cell 102b are indicated by arrows in FIG. 1B.

The applied potential difference causes charges, usually electrons, in the charge-detrap electrode 126 to flow from a low potential region to a high potential region, generating an electric current and produces thermal energy as a result. The generated thermal energy may also be referred to as Joule heat, resistive heat, or ohmic heat. The charge-detrap electrode 126 may be thermally coupled to the selected memory cell 102a and the generated thermal energy may be conducted to the gate dielectric layer 116a and the tunnel barrier layer 122. Electron traps that may be present in the gate dielectric layer 116a and/or the tunnel barrier layer 122 may be advantageously cured, and device performance of the NVM device may be substantially recovered back to the initial designed value.

The temperature produced by the generated thermal energy from the charge-detrap electrode 126 may be controlled by optimizing the applied pulse width and/or the duration of the applied voltages. The charge-detrap operation may be initiated after a predetermined number of cycles or after a predetermined period.

Depending on the electro-thermal performance required for the NVM device 100, the charge-detrap electrode 126 may be a doped or an undoped electrode and/or a silicided or an un-silicided electrode. Doping a charge-detrap electrode may lower the resistance, thereby generating a lower level of thermal energy. Similarly, a silicided charge-detrap electrode may also lower the resistance to achieve the desired level of heating temperature.

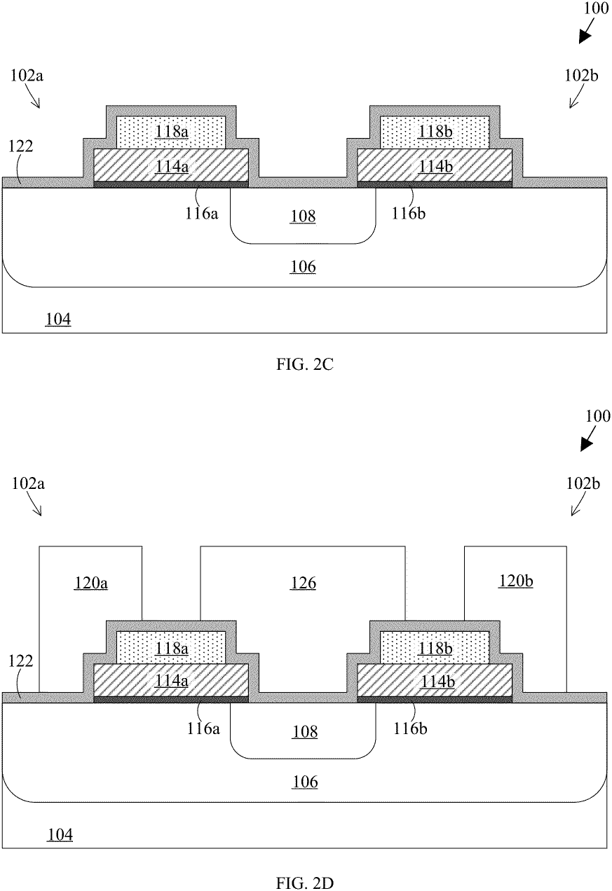

FIGS. 2A to 2E are cross-sectional views that illustrate a method of forming the NVM device 100 in FIG. 1B, according to an embodiment of the disclosure. The NVM device 100 may be part of a plurality of NVM devices arranged in an array configuration of rows and columns in a memory cell region of a semiconductor device. Certain structures may be fabricated, for example, using known processes and techniques, and specifically disclosed processes and methods may be used to achieve individual aspects of the present disclosure.

As used herein, “deposition techniques” refer to the process of applying a material over another material (or the substrate). Exemplary techniques for deposition include, but not limited to, spin-on coating, sputtering, chemical vapor deposition (CVD), physical vapor deposition (PVD), molecular beam deposition (MBD), pulsed laser deposition (PLD), liquid source misted chemical deposition (LSMCD), or atomic layer deposition (ALD).

Additionally, “patterning techniques” include deposition of material or photoresist, patterning, exposure, development, etching, cleaning, and/or removal of the material or photoresist as required in forming a described pattern, structure, or opening. Exemplary examples of techniques for patterning include, but not limited to, wet etch photolithographic processes, dry etch photolithographic processes, or direct patterning processes.

As illustrated in FIG. 2A, a substrate 104 may be provided. In an embodiment of the disclosure, the substrate 104 may include P-type conductivity dopants, such as, but not limited to, boron, aluminum, or gallium. The substrate 104 may have a region defined to form a memory cell 102a and another region to form a memory cell 102b. As disclosed above, the memory cell 102b may a mirror image of the memory cell 102a. Therefore, for brevity, the method of forming the NVM device 100 may be described with reference to the memory cell 102a, and the memory cell 102b may be formed using similar processes and methods.

The memory cell 102a may include a gate dielectric layer 116a, a floating gate 114a, and a mask layer 118a. A layer of gate dielectric material (not shown), a layer of floating gate material (not shown), and a layer of mask material (not shown) may be sequentially deposited over the substrate 104 using various deposition techniques. Using one or more patterning techniques, the layer of gate dielectric material, the layer of floating gate material, and the layer of mask material may be patterned to form the gate dielectric layer 116a, the floating gate 114a, and the mask layer 118a.

According to an embodiment of the disclosure, the memory cell 102a may further include dielectric spacers 202a, as illustrated in FIG. 2A. The dielectric spacers 202a may be formed adjacent to the mask layer 118a such that the mask layer 118a may be arranged therebetween. An exemplary process to form the dielectric spacers 202a may be described herein. After sequentially depositing the layer of gate dielectric material, the layer of floating gate material, and the layer of mask material over the substrate 104, the layer of mask material may be patterned using a patterning technique to form the mask layer 118a. A layer of dielectric spacer material (not shown) may be deposited over the substrate 104, the layer of floating gate material, and the mask layer 118a using a deposition technique. The layer of dielectric spacer material may be subsequently patterned using a patterning technique to form the dielectric spacers 202a. Using the mask layer 118a and the dielectric spacers 202a as masking features, the layer of floating gate material and the layer of gate dielectric layer may be patterned using a patterning technique to form the gate dielectric layer 116a and the floating gate 114a of the memory cell 102a. In this embodiment of the disclosure, the gate dielectric layer 116a and the floating gate 114a may have a width wider than a width of the mask layer 118a.

The memory cell 102b may be similarly formed using the above-disclosed plurality of processes to form a gate dielectric layer 116b, a floating gate 114b, and a mask layer 118b. The memory cell 102b may further include dielectric spacers 202b, according to an embodiment of the disclosure. The dielectric spacers 202b may be formed adjacent to the mask layer 118b such that the mask layer 118b may be arranged therebetween.

In an embodiment of the disclosure, the layer of gate dielectric material may include an electrically insulative material, such as a dielectric material with a high dielectric constant; also refer to as a high-k dielectric material or silicon dioxide. In another embodiment of the disclosure, the layer of floating gate material may include a conductive material, such as polysilicon or amorphous silicon. In yet another embodiment of the disclosure, the layer of mask material may include an electrically insulative hard mask material that may be suitable to protect underlying materials from potential damage caused during the fabrication process, such as oxide-nitride-oxide (ONO), oxide-nitride (ON), polysilicon oxide, polysilicon nitride, or combinations thereof. In a further embodiment of the disclosure, the dielectric spacer material may include a sacrificial dielectric material formed of silicon oxide, silicon nitride, silicon oxynitride, or a combination thereof.

FIG. 2B illustrates the NVM device 100 after forming dielectric spacers 204a, dielectric spacers 204b, a source region 108, and a memory well region 106, according to an embodiment of the disclosure. The dielectric spacers 204b may be formed using an exemplary process as described herein. A layer of dielectric material (not shown) may be deposited over the substrate 104 using a deposition technique and patterned using a patterning technique to form the dielectric spacers 204a, 204b. The dielectric spacers 204a may be formed at least partially adjacent to the dielectric spacers 202a, the floating gate 114a, and the gate dielectric layer 116a such that the dielectric spacers 202, the floating gate 114a, and the gate dielectric layer 116a may be arranged between the dielectric spacers 204a.

Similarly, the dielectric spacers 204b may be formed adjacent to the dielectric spacers 202b, the floating gate 114b, and the gate dielectric layer 116b such that the dielectric spacers 202b, the floating gate 114b, and the gate dielectric layer 116b may be arranged between the dielectric spacers 204b. In an embodiment of the disclosure, the dielectric spacers 204a and the dielectric spacers 204b may include the same material composition as the dielectric spacers 202a, 202b. In another embodiment of the disclosure, the dielectric spacers 204a and the dielectric spacers 204b may include a dielectric material of different material composition as the dielectric spacers 202a, 202b, and may include a sacrificial material formed of silicon oxide, silicon nitride, silicon oxynitride, or a combination thereof.

According to another embodiment of the disclosure, the dielectric spacers 202a and the dielectric spacers 202b may be removed using a material removal technique before forming the dielectric spacers 204a and the dielectric spacers 204b. The dielectric spacers 204a may be formed adjacent to the mask layer 118a, the floating gate 114a, and the gate dielectric layer 116a such that the mask layer 118a, the floating gate 114a, and the gate dielectric layer 116a may be arranged between the dielectric spacers 204a. Similarly, the dielectric spacers 204b may be formed at least partially adjacent to the mask layer 118b, the floating gate 114b, and the gate dielectric layer 116b such that the mask layer 118b, the floating gate 114b, and the gate dielectric layer 116b may be arranged between the dielectric spacers 204b. This embodiment, however, is not shown in the accompanying drawings.

The source region 108 may be formed in the substrate 104 between the memory cell 102a and the memory cell 104a, as illustrated in FIG. 2B. The source region 108 may be formed at least partially within the substrate 104. The source region 108 may be a doped region formed by introducing dopants into the substrate 104 using an ion implantation process. In an embodiment of the disclosure, the source region 108 may include dopants having a different conductivity from the substrate 104, for example, N-type conductivity dopants such as, but not limited to, arsenic, phosphorus, or antimony.

The memory well region 106 may be formed in the substrate 104 such that the source region 108 may be arranged therewithin. The memory well region 106 may be a doped region formed by introducing dopants into the substrate 104 using an ion implantation process. In an embodiment of the disclosure, the memory well region 106 may include dopants having the same conductivity as the substrate 104, for example, P-type conductivity dopants such as, but not limited to, boron, aluminum, or gallium. The dopant concentrations and/or dopant depths of the memory well region 106 and the source region 108, for example, may vary depending on the technology node and design requirements for the NVM device 100.

FIG. 2C illustrates the NVM device 100 after forming a tunnel barrier layer 122, according to an embodiment of the disclosure. The dielectric spacers 202a and the dielectric spacers 204a of the memory cell 102a, and the dielectric spacers 202b and the dielectric spacers 204b of the memory cell 102b, as illustrated in FIG. 2B, may be removed using a material removal technique before forming the tunnel barrier layer 122.

The tunnel barrier layer 122 may be deposited over the substrate 104 using a deposition technique; the deposition technique being preferably a conformal deposition process. The conformal deposition process may include, but not limited to, an ALD process or a highly-conformal CVD process. The tunnel barrier layer 122 may be formed at least partially over the mask layer 118a and at least partially adjacent to the floating gate 114a of the memory cell 102a. The tunnel barrier layer 122 may further extend over to the memory cell 102b and may be formed over the mask layer 118b and adjacent to the floating gate 114b. In an embodiment of the disclosure, the tunnel barrier layer 122 may include a dielectric material such as silicon dioxide.

FIG. 2D illustrates the NVM device 100 after forming a gate electrode 120a for the memory cell 102a, a gate electrode 120b for the memory cell 102b, and a charge-detrap electrode 126 between the gate electrode 120a and the gate electrode 120b, according to an embodiment of the disclosure. A conductive material (not shown) may be deposited over the tunnel barrier layer 122 using a deposition technique and patterned using a patterning technique to form the gate electrode 120a, the gate electrode 120b, and the charge-detrap electrode 126. The gate electrode 120a and the charge-detrap electrode 126 may be arranged at laterally opposite sides of the floating gate 114a. Similarly, the gate electrode 120b and the charge-detrap electrode 126 may be arranged at laterally opposite sides of the floating gate 114b.

Portions of the tunnel barrier layer 122 may be exposed after performing the patterning technique. For example, portions of the tunnel barrier layer 122 over the mask layer 118a and the mask layer 118b may be exposed. In an embodiment of the disclosure, the conductive material may include polysilicon, amorphous silicon, metals or alloys, for example, titanium nitride, tantalum nitride, tungsten, or combinations thereof.

However, the gate electrode 120a, the gate electrode 120b, and the charge-detrap electrode 126 may not necessarily be formed of the same conductive material. Accordingly, the gate electrode 120a, the gate electrode 120b, and the charge-detrap electrode 126 may be formed separately and not concurrently as described above.

FIG. 2E illustrates the NVM device 100 after forming spacers 124, a dielectric liner 130a and a drain region 110a for the memory cell 102a, and a dielectric liner 130b and a drain region 110b for the memory cell 102b, according to an embodiment of the disclosure. The spacers 124 may be formed by depositing a dielectric material over sidewalls of the gate electrode 120a, sidewalls of the gate electrode 120b, and sidewalls of the charge-detrap electrode 126 using a deposition technique; the deposition technique being preferably a conformal deposition process. The spacers 124 may include a single-layered dielectric material or a multi-layered dielectric material. In an embodiment of the disclosure, the spacers 124 may include an electrically insulative dielectric material such as, but not limited to, silicon dioxide, silicon nitride, silicon oxynitride, combinations thereof, or other electrically insulative materials suitable to electrically isolate the gate electrode 120a, the gate electrode 120b, and the charge-detrap electrode 126 from adjacent conductive features.

In this embodiment of the disclosure, the spacers 124 may be a multi-layered dielectric material, including a dielectric material 124a and a dielectric material 124b. The dielectric material 124a may include a nitride material, such as silicon nitride, and the dielectric material 124b may include a nitride material, such as silicon nitride an oxide material, such as silicon dioxide.

The dielectric liner 130a for the memory cell 102a may be formed adjacent to the mask layer 118a and the floating gate 114a. Similarly, the dielectric liner 130b for the memory cell 102b may be formed adjacent to the mask layer 118b and the floating gate 114b. In an embodiment of the disclosure, the dielectric liner 130a and the dielectric liner 130b may include the same dielectric material composition as the spacers 124, for ease of fabrication. However, the dielectric liner 130a and the dielectric liner 130b may include a dielectric material of different material compositions from the spacers 124.

The drain region 110a and the drain region 110b may be formed in the substrate 104 such that the floating gate 114a of the memory cell 102a may be arranged between the drain region 110a and the source region 108, and the floating gate 114b of the memory cell 102b may be arranged between the drain region 110b and the source region 108. Similar to the source region 108, the drain region 110a and the drain region 110b may be formed at least partially within the substrate 104. The drain region 110a and the drain region 110b may be doped regions formed by introducing dopants into the substrate 104 using an ion implantation process. In an embodiment of the disclosure, the drain region 110a and the drain region 110b may include dopants having the similar conductivity as the source region 108, for example, N-type conductivity dopants, even though the drain regions 110a, 110b may not necessarily include the same dopants as the source region 108.

In an embodiment of the disclosure, the gate electrodes 120a, 120b may undergo a silicidation process to form a layer of metal silicide 206, such as silicon silicide, over the gate electrode 120a and the gate electrode 120b. The charge-detrap electrode 126 may or may not undergo a silicidation process. The silicidation process may lower the resistance of the charge-detrap electrode 126. The NVM device 100 in FIG. 2E illustrates the charge-detrap electrode 126 as an un-silicided electrode.

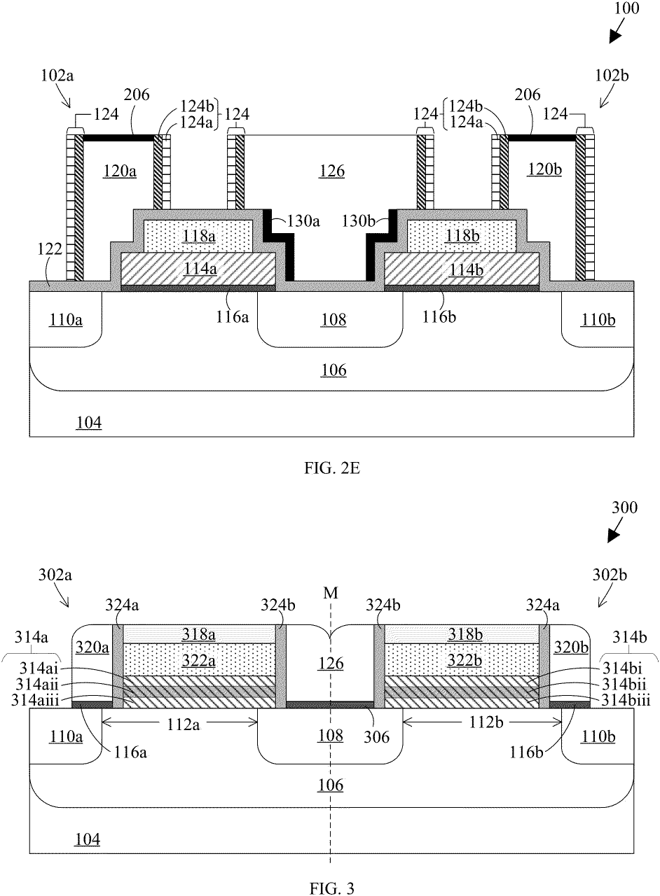

FIG. 3 is a cross-sectional view of an NVM device 300, according to an alternative embodiment of the disclosure. The NVM device 300 is similar to the NVM device 100 in FIG. 1B, and thus common features are labeled with the same reference numerals and need not be discussed.

The NVM device 300 may include a memory cell 302a and a memory cell 302b. The memory cell 302a and the memory cell 302b may be mirror images of each other about an axis M through the center of a source region 108. The source region 108 may be a shared source region between the memory cell 302a and the memory cell 302b.

Similar to the NVM device 100, the NVM device 300 may also utilize a charge retention mechanism. However, unlike the NVM device 100 which may employ a floating gate, the NVM device 300 may employ a dielectric charge-trap layer for charge storage. For example, the memory cell 302a of the NVM device 300 may include a dielectric charge-trap layer 314a for charge storage. The dielectric charge-trap layer 314a may be arranged at least partially over a channel region 112a. The dielectric charge-trap layer 314a may be multi-layered; for example, the dielectric charge-trap layer 314a may include an ONO layer of silicon dioxide 314ai, silicon nitride 314aii, and silicon dioxide 314aiii. Charges may be injected into the silicon nitride layer 314aii through the silicon dioxide layer 314ai during a program operation. During an erase operation, hot holes may be generated at the drain region 110a and may get injected into the silicon nitride layer 314aii through the silicon dioxide layer 314ai to neutralize the stored charges therewithin, using a hot hole injection (HHI) mechanism. Similarly, the memory cell 302b may include a dielectric charge-trap layer 314b at least partially arranged over the channel region 112b for charge storage.

The NVM device 300 may further include a select gate 320a and a control gate 322a for the memory cell 302a, and a select gate 320b and a control gate 322a for the memory cell 302b, unlike the NVM device 100 which employs a dual-function gate for select and erase functionalities.

Referring to the memory cell 302a, the control gate 322a may be arranged over the dielectric charge-trap layer 314a. A mask layer 318a may be arranged over the control gate 322a. The mask layer 318a may be synonymous with the mask layer 118a of the memory cell 102a of the NVM device 100 in FIG. 1B in that the mask layer 318a may protect the control gate 322a and the dielectric charge-trap layer 314a from potential damage that may occur during subsequent fabrication processes.

The select gate 320a may be at least partially arranged over the channel region 112a. For example, a portion of the select gate 320a may be arranged at least partially over the channel region 112a and another portion of the select gate 320a may be arranged over a drain region 110a. The gate dielectric layer 116a may separate the select gate 320a from the substrate 104. The select gate 320a may be further arranged adjacent to the dielectric charge-trap layer 314a, the control gate 322a, and the mask layer 318a. The control gate 322a may be electrically isolated from the select gate 320a and the charge-detrap electrode 126 by an insulator layer 324a and an insulator layer 324b, respectively.

Similarly, the memory cell 302b may include a select gate 320b, a control gate 322b, a dielectric charge-trap layer 314b, a mask layer 318b, a gate dielectric layer 116b, an insulator layer 324a and an insulator layer 324b arranged in a similar configuration as the memory cell 302a.

Similar to the NVM device 100 in FIG. 1B, the charge-detrap electrode 126 may be an electrically isolated and thermally coupled electrode arranged between the memory cell 302a and the memory cell 302b. For example, the charge-detrap electrode 126 may be electrically isolated from the control gate 322a, the control gate 322b, and the substrate 104 by the insulator layers 324b, and a dielectric layer 306, respectively.

As presented in the above disclosure, NVM devices having a charge-detrap mechanism and methods of forming the same are presented. The NVM devices may include a plurality of memory cells and a charge-detrap electrode that traverses the plurality of memory cells. The charge-detrap electrode may be thermally coupled to and electrically isolated from the plurality of memory cells.

As mentioned above, electron traps may be undesirably formed in the gate dielectric layer and/or the tunnel barrier layer during the iterative cycling of a program operation and an erase operation of an NVM device, trapping charges therewithin. The charge-detrap electrode may facilitate the NVM device to detrap, or expel, undesirably trapped charges in the gate dielectric layer and/or the tunnel barrier layer of the plurality of memory cells by providing a charge-detrap mechanism, For example, the charge-detrap detrap may perform a charge-detrap operation to electro-thermally anneal the gate dielectric layer and/or the tunnel barrier layer, enabling trapped charges to effectively detrap, or expel, from the NVM device. The charge-detrap operation may enable the NVM device to recover device performance and achieve improved reliability.

The charge-detrap electrode may be operated independently from the NVM device. The voltages required to initiate a charge-detrap operation may be relatively lower than the required voltages for operations of the corresponding memory cells, thereby minimizing causing additional stress to the NVM device. Furthermore, the standalone nature charge-detrap electrode may enable designers to easily integrate the charge-detrap electrode into existing designs of the NVM devices, without impacting the device performances. For example, the charge-detrap electrode may be integrated at a sector level of the NVM device or a chip level of the NVM device.

The terms “upper”, “bottom”, “over”, “under”, and the like in the description and the claims, if any, are used for descriptive purposes and not necessarily for describing permanent relative positions. It is to be understood that the terms so used are interchangeable under appropriate circumstances such that the embodiments of the devices described herein are, for example, capable of operation in other orientations than those illustrated or otherwise described herein.

Additionally, the formation of a first feature over or on a second feature in the description that follows may include embodiments in which the first and second features are formed in direct contact, and may also include embodiments in which additional features may be formed interposing the first and second features, such that the first and second features may not be in direct contact.

Similarly, if a method is described herein as involving a series of steps, the order of such steps as presented herein is not necessarily the only order in which such steps may be performed, and certain of the stated steps may possibly be omitted and/or certain other steps not described herein may possibly be added to the method. Furthermore, the terms “comprise”, “include”, “have”, and any variations thereof, are intended to cover a non-exclusive inclusion, such that a process, method, article, or device that comprises a list of elements is not necessarily limited to those elements, but may include other elements not expressly listed or inherent to such process, method, article, or device. Occurrences of the phrase “in an embodiment” herein do not necessarily all refer to the same embodiment.

In addition, unless otherwise indicated, all numbers expressing quantities, ratios, and numerical properties of materials, reaction conditions, and so forth used in the specification and claims are to be understood as being modified in all instances by the term “about”.

Furthermore, approximating language, as used herein throughout the specification and claims, may be applied to modify any quantitative representation that could permissibly vary without resulting in a change in the basic function to which it is related. Accordingly, a value modified by a term or terms, such as “approximately”, “about,”, “substantially” is not limited to the precise value specified. In some instances, the approximating language may correspond to the precision of an instrument for measuring the value. In other instances, the approximating language may correspond to within normal tolerances of the semiconductor industry. For example, “substantially coplanar” means substantially in a same plane within normal tolerances of the semiconductor industry, and “substantially perpendicular” means at an angle of ninety degrees plus or minus a normal tolerance of the semiconductor industry.

While several exemplary embodiments have been presented in the above detailed description of the device, it should be appreciated that a number of variations exist. It should further be appreciated that the embodiments are only examples, and are not intended to limit the scope, applicability, dimensions, or configuration of the device in any way. Rather, the above detailed description will provide those skilled in the art with a convenient road map for implementing an exemplary embodiment of the device, it being understood that various changes may be made in the function and arrangement of elements and method of fabrication described in an exemplary embodiment without departing from the scope of this disclosure as set forth in the appended claims.

What is claimed is:

1. A semiconductor device, comprising:
a memory cell, the memory cell comprising:
a substrate comprising a source region and a drain region, and a channel region arranged between the source region and the drain region;
a floating gate arranged over the channel region, the floating gate having a first side and a second side laterally opposite the first side; and
a gate electrode arranged adjacent to the first side of the floating gate; and
a charge-detrap electrode arranged adjacent to the second side of the floating gate.

2. The semiconductor device of claim 1, wherein the charge-detrap electrode is arranged over the source region of the memory cell.

3. The semiconductor device of claim 1, wherein the charge-detrap electrode is arranged over the floating gate of the memory cell.

4. The semiconductor device of claim 1, wherein the charge-detrap electrode is thermally coupled to the memory cell.

5. The semiconductor device of claim 1, wherein the charge-detrap electrode is electrically isolated from the memory cell.

6. The semiconductor device of claim 1, further comprising contacts, and the contacts are arranged at end portions of the charge-detrap electrode.

7. The semiconductor device of claim 1, wherein the memory cell further comprises a mask layer arranged over the floating gate, and the charge-detrap electrode is arranged over the mask layer.

8. The semiconductor device of claim 7, wherein the memory cell further comprises a tunnel barrier layer arranged over the mask layer, the floating gate, the source region, and the drain region, and the tunnel barrier layer separates the charge-detrap electrode from the mask layer, the floating gate, and the source region.

9. The semiconductor device of claim 1, wherein the charge-detrap electrode comprises the same material composition as the gate electrode.

10. The semiconductor device of claim 1, wherein the gate electrode of the memory cell is a dual-function gate electrode that functions as a select gate and an erase gate.

11. A semiconductor device, comprising:
a memory device comprising a plurality of memory cells, wherein each memory cell comprising:
a substrate comprising a source region and a drain region, and a channel region arranged between the source region and the drain region;
a floating gate arranged over the channel region, the floating gate having a first side and a second side laterally opposite the first side; and
a gate electrode arranged adjacent to the first side of the floating gate; and
a charge-detrap electrode arranged parallel to the plurality of memory cells and adjacent to the second side of the floating gate of each memory cell.

12. The semiconductor device of claim 11, further comprising contacts, the contacts are arranged at end portions of the charge-detrap electrode, and the plurality of memory cells are arranged between the contacts.

13. The semiconductor device of claim 11, wherein the gate electrode is a shared gate electrode for the plurality of memory cells, and the gate electrode forms a word line of the memory device.

14. The semiconductor device of claim 11, wherein the source region is a shared source region for the plurality of memory cells, and the source region forms a source line of the memory device.

15. The memory device of claim 14, wherein the source region is arranged below the charge-detrap electrode.

16. A method of forming a semiconductor device, comprising:
forming a source region in a substrate;
forming a floating gate over the substrate and adjacent to the source region;
forming a gate electrode and a charge-detrap electrode at laterally opposite sides of the floating gate; and
forming a drain region in the substrate spaced apart from the source region, wherein the gate electrode is arranged at least partially over the drain region and the charge-detrap electrode is arranged at least partially over the source region.

17. The method of claim 16, further comprises forming a tunnel barrier layer arranged over the floating gate to electrically isolate the charge-detrap electrode therefrom.

18. The method of claim 16, wherein forming the gate electrode and the charge-detrap electrode comprises:
depositing a conductive material over the substrate; and
patterning the conductive material to form the gate electrode and the charge-detrap electrode.

19. The method of claim 16, further comprises forming contacts at end portions of the charge-detrap electrode.

20. The method of claim 16, further comprises performing a silicidation process on the gate electrode to form a layer of metal silicide.
